(19) United States
(12) Patent Application Publication
(10) Pub. No.: US 2026/0206214 A1
(43) Pub. Date: Jul. 16, 2026

(54) TECHNIQUES FOR BIT LINE CONTACT ACTIVE AREA REDUCTION

(71) Applicant: Micron Technology, Inc., Boise, ID (US)

(72) Inventors: Ping Chieh Chiang, Bosie, ID (US); Vivek Yadav, Boise, ID (US)

(21) Appl. No.: 19/431,903

(22) Filed: Dec. 23, 2025

Related U.S. Application Data
(60) Provisional application No. 63/746,193, filed on Jan. 16, 2025.

(51) Int. Cl. H10B 12/00

(52) U.S. Cl. CPC H10B 12/485; H10B 12/02

(57) ABSTRACT

Methods, systems, and devices for techniques for bit line contact active area reduction are described. In some examples, the memory system may include multiple silicon structures vertically extending through an oxide layer. The multiple silicon structures may include a first set of silicon structures that are each coupled with a respective bit line of the memory system and a second set of silicon structures that are coupled with a respective memory component of the memory system. The memory system may also include multiple nitride structures that each at least partially surround a respective silicon structure of the first set of silicon structures.

### CROSS REFERENCE TO RELATED APPLICATION(S)

The present Application for Patent claims priority to U.S. Patent Application No. 63/746,193 by Chiang et al., entitled “TECHNIQUES FOR BIT LINE CONTACT ACTIVE AREA REDUCTION,” filed January 16, 2025, which is assigned to the assignee hereof, and which is expressly incorporated by reference in its entirety herein.

### TECHNICAL FIELD

The following relates to one or more systems for memory, including techniques for bit line contact active area reduction.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports techniques for bit line contact active area reduction in accordance with examples as disclosed herein.

FIG. 2 shows an example of an array that supports techniques for bit line contact active area reduction in accordance with examples as disclosed herein.

FIG. 3 shows an example of a manufacturing process that supports techniques for bit line contact active area reduction in accordance with examples as disclosed herein.

FIG. 4 shows a flowchart illustrating a method or methods that support techniques for bit line contact active area reduction in accordance with examples as disclosed herein.

### DETAILED DESCRIPTION

During manufacturing of a memory system, an active area (e.g., a polysilicon region) of a bit line contact included in a transistor structure of the memory system may be reduced to increase isolation between the active area of the bit line contact and a memory cell contact included in a neighboring transistor structure. Increasing isolation between the bit line contact and the memory cell contact may mitigate unwanted electrical communication between the bit line contact and the memory cell contact. One method to reduce the active area of the bit line contact may include forming a liner around a recessed active area. However, this method may also include performing a liner punch, which may prove challenging and may potentially damage the liner resulting in sidewall blowout issues.

As described herein, techniques may include an alternative method to reduce the active area of the bit line contact. The techniques may include etching a portion of an oxide material that surrounds a silicon column (or bit line contact) to form a cavity that surrounds the silicon column. Additionally, or alternatively, the techniques may include etching some of the silicon column through the cavity such that a portion of the silicon column is reduced (e.g., a diameter of the bit line contact is reduced) and filling the cavity with nitride to create a nitride island that surrounds the reduced portion of the silicon column. Further, the techniques may include removing the portion of the silicon column to create a cavity in the nitride island and forming polysilicon in the cavity of the nitride island to create an active area of the bit line contact.

As a result, a manufacturing system may create a memory system that includes one or more transistor structures that each include a nitride island that surrounds a reduced active area of a bit line contact of the transistor structure. Not only does the reduced active area promote increased electrical isolation between the bit line contact and the memory cell contact of neighboring transistor structures, but the nitride island surrounding the reduced active area may improve bit line capacitance as well as prevent sidewall blowouts (e.g., of the polysilicon or other materials).

In addition to applicability in memory systems as described herein, techniques for bit line contact active area reduction may be generally implemented to improve the sustainability of various electronic devices and systems. As the use of electronic devices has become even more widespread, the amount of energy used, and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by reducing defects in the manufacturing process which may result in reduce electronic waste, among other benefits.

Features of the disclosure are illustrated and described in the context of systems and architectures. Features of the disclosure are further illustrated and described in the context of an array, a manufacturing process, and flowcharts.

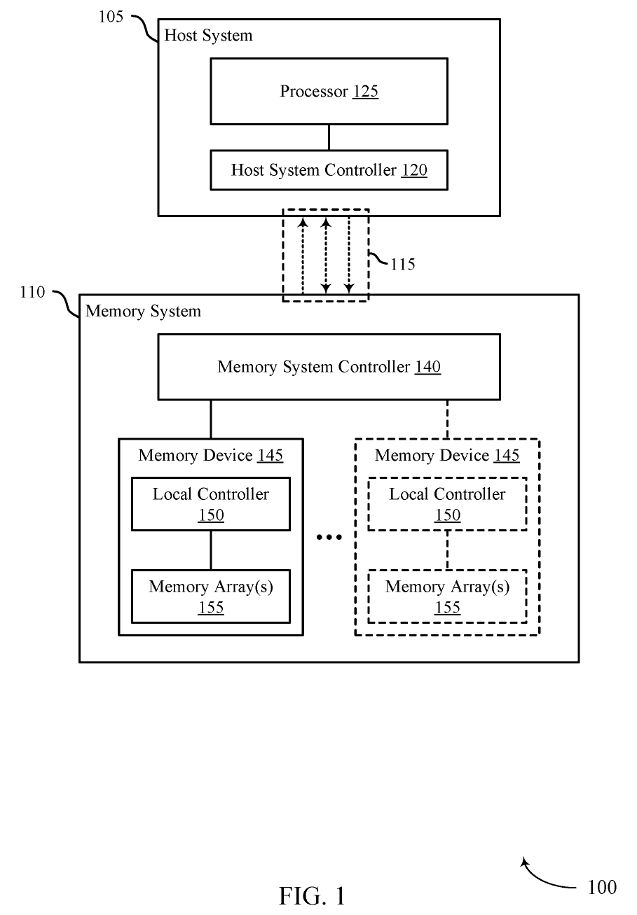

FIG. 1 shows an example of a system 100 that supports techniques for bit line contact active area reduction in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105 and may respond to commands from the host system 105 (e.g., from a host system controller 120). For example, a memory system 110 (e.g., a memory system controller 140) may receive a write command indicating that the memory system 110 is to store data received from a host system 105, or receive a read command indicating that the memory system 110 is to provide data stored in a memory device 145 to a host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of a memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

As described herein, a manufacturing system of the memory system 110 may perform one or more manufacturing process to reduce an active area of a bit line contact of the memory system 110. The one or more manufacturing processes may include etching a portion of an oxide material that surrounds a silicon column (or a bit line contact) to form a cavity that surrounds the silicon column. Additionally, or alternatively, the one or more manufacturing processes may include etching some of the silicon column through the cavity such that a portion of the silicon column is reduced (e.g., a diameter of the bit line contact is reduced) and filling the cavity with nitride to create a nitride island that surrounds the reduced portion of the silicon column. Additionally, or alternatively, the one or more manufacturing processes may include removing the portion of the silicon column to create a cavity in the nitride island and forming polysilicon in the cavity of the nitride island to create the reduced active area of the bit line contact. The reduction in the active area of the bit line contact may increase isolation between the bit line contact and a memory cell contact of neighboring transistor structures. Additionally, the addition of the nitride island surrounding the reduced active area may improve bit line capacitance as well as prevent sidewall blowouts (e.g., of the polysilicon or other materials).

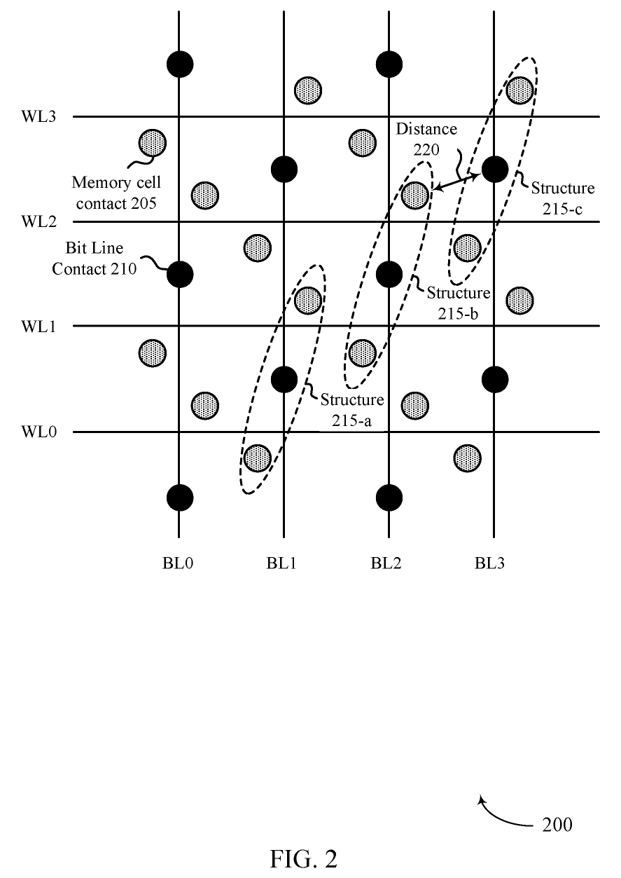

FIG. 2 shows an example of an array 200 that supports techniques for bit line contact active area reduction in accordance with examples as disclosed herein. In some examples, the array 200 may be an example of the memory array 155 as described with reference to FIG. 1.

As shown in FIG. 2, the array 200 of a memory system may include a set of bit lines (e.g., BL0, BL1, BL2, and BL3) extending in a first direction and a set of word lines (e.g., WL0, WL1, WL2, and WL3) extending in a second direction perpendicular to the first direction. A memory cell may be located at each intersection of a respective word line and a respective bit line and each memory cell of the array 200 may be configured to store data (e.g., one or more bits of data).

In some examples, the array 200 may include one or more transistor structures 215 that may enable the memory system to access (e.g., read or write) data stored at the memory cells of the array 200. Each transistor structure 215 may include a substrate (e.g., p-type substrate) that houses two buried word lines, a bit line contact 210, and two memory cell contacts 205. The bit line contact 210 may be coupled with a bit line shared by a pair of memory cells (or memory cell components or capacitors) that are each coupled with a respective memory cell contact 205 of the two memory cell contacts 205 of the transistor structure 215. For example, a transistor structure 215-a of the array 200 may include a substrate that houses buried word lines WL0 and WL1, a bit line contact 210 coupled with a BL1, and two memory cell contacts 205 that are each coupled with a memory cell at an intersection of the WL0 and the BL1 or a memory cell at an intersection of the WL1 and the BL1.

To access (e.g., read or write) data at a memory cell of the array 200, the memory system may activate (or enable) a word line and a bit line corresponding to the memory cell, which may cause charge sharing to occur between the memory cell and the bit line. For example, to access a memory cell at the intersection of the WL1 and the BL1, the memory system may activate the WL1 and the BL1, which may cause charge sharing to occur between the memory cell contact 205 corresponding to the memory cell and the bit line contact 210 corresponding to the BL1 through the substrate of the transistor structure 215-a.

In some examples, an active area (or a polysilicon portion) of a bit line contact 210 of a transistor structure 215 and a memory cell contact 205 of a neighboring transistor structure 215 may be relatively close to one another. For example, a memory cell contact 205 of the transistor structure 215-b may be separated from an active area of the bit line contact 210 of the transistor structure 215-c by a distance 220. In some examples, the distance 220 may not result in sufficient electrical isolation between the memory cell contact 205 and the bit line contact 210. As a result, unintended electrical communication may occur between the bit line contact 210 and the memory cell contact 205 of neighboring transistor structures 215.

of the transistor structure 215-b may be separated from an active area of the bit line contact 210 of the transistor structure 215-c by a distance 220. In some examples, the distance 220 may not result in sufficient electrical isolation between the memory cell contact 205 and the bit line contact 210. As a result, unintended electrical communication may occur between the bit line contact 210 and the memory cell contact 205 of neighboring transistor structures 215.

Therefore, a manufacturing process may be performed to increase the distance 220. As an example, the manufacturing process may include recessing the active area of a bit line contact 210 and forming a liner around the recessed active area of the bit line contact 210 such that the physical distance between the active area of the bit line contact 210 and the neighboring memory cell contact 205 is bigger. Additionally, various materials may be used in the liner to increase electrical isolation, in some cases. However, this manufacturing process may include punching through the bottom of the liner (e.g., to enable the bit line contact 210 to contact the substrate), which may be challenging and could potentially damage the sides of the liner.

The manufacturing process as described herein may increase the physical distance 220 (and/or the electrical isolation) between the active areas of bit line contacts 210 and memory cell contacts 205 of neighboring transistor structures 215 while protecting the structural integrity of the transistor structures 215. The manufacturing process may include forming a cavity around a portion of a bit line contact 210 (e.g., by removing some oxide material that surrounds the bit line contact 210). Further, the manufacturing process may include recessing the portion of the bit line contact 210 (e.g., such that a horizontal cross-sectional area of the portion of the bit line contact 210 is reduced).

Additionally, the manufacturing process may include forming nitride in the cavity such that nitride material surrounds the portion of the bit line contact 210. In some cases, the nitride material may further increase electrical isolation of the bit line contact 210 from other components. Further, the manufacturing process may include removing the portion of the bit line contact 210 to generate a cavity in the nitride material and forming material (e.g., polysilicon material) in the cavity of the nitride material to create the active area of the bit line contact 210. This manufacturing process may be applied to each bit line contact 210 of the array 200. Using this manufacturing process, the active areas of bit line contacts 210 may be reduced thereby increasing the distance 220 between the active areas of bit line contacts 210 and the memory cell contacts 205 of neighboring transistor structures 215.

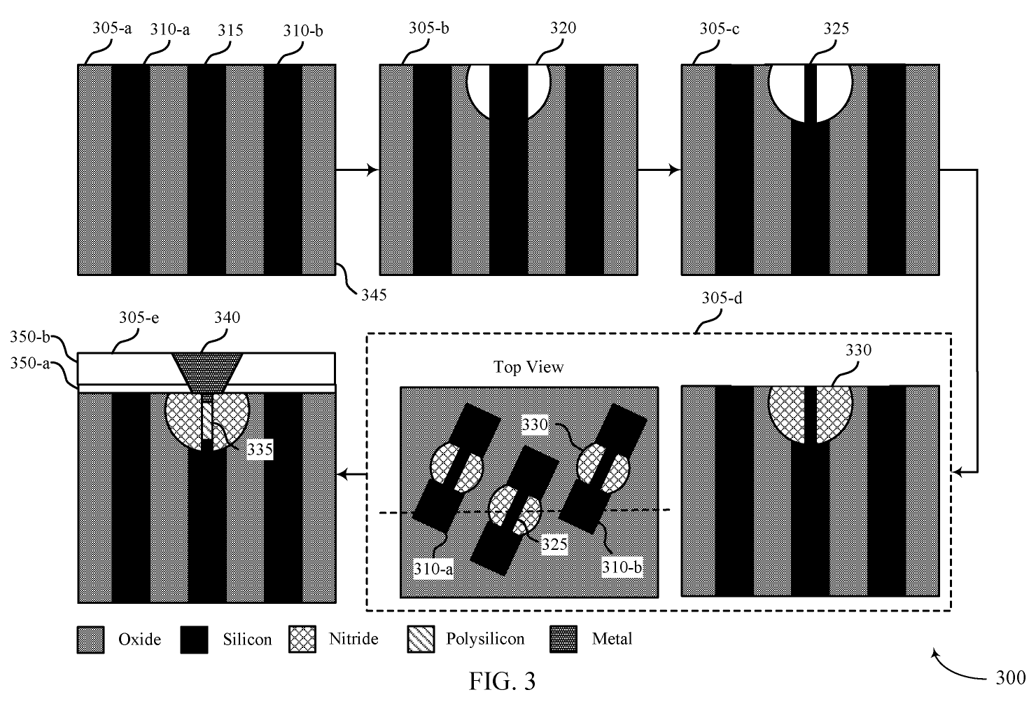

FIG. 3 shows an example of a manufacturing process 300 that supports techniques for bit line contact active area reduction in accordance with examples as disclosed herein. The manufacturing process 300 may illustrate portions 305 during different stages of the manufacturing process 300. In some examples, a portion 305 may include a vertical cross section of one or more transistor structures. For example, the portion 305 may include a vertical cross section of the transistor structure 215-a, the transistor structure 215-b, and the transistor structure 215-c taken from the center of the memory cell contact 205 of the transistor structure 215-a, the bit line contact 210 of the transistor structure 215-b, and the memory cell contact 205 of the transistor structure 215-c.

The manufacturing process 300 may include one or more first operations to create the portion 305-a. The one or more first operations may include forming a column 310-a, a column 310-b, and a column 315 in a layer 345. As shown in FIG. 3, the column 310-a, the column 310-b, and the column 315 may extend vertically through the layer 345. The column 310-a may be an example of a memory cell contact of a first transistor structure, the column 315 may be an example of a bit line contact of a second transistor structure, and the column 310-b may be an example of a memory cell portion of a third transistor structure. In some examples, the column 310-a, the column 315, and the column 310-b may include silicon material and the layer 345 may include oxide material. In some examples, the columns 310 may be configured to couple (e.g., indirectly or directly) with a memory component (or a capacitor) of a respective memory cell of an array and the columns 315 may be configured to couple (e.g., indirectly or directly) with a respective bit line of the array.

Additionally, the manufacturing process 300 may include one or more second operations to create the portion 305-b. The one or more second operations may include removing (e.g., via oxide vapor etch) part of the layer 345 to form a cavity 320. As shown in FIG. 3, the cavity 320 may at least partially surround a portion of the column 315.

Additionally, the manufacturing process 300 may include one or more third operations to create the portion 305-c. The one or more third operations may include removing, through the cavity 320, a first part of the portion of the column 315. In some examples, removing the first part of the portion of the column 325 may create a column 325. In some examples, the column 325 may have smaller horizontal cross-sectional area (or a smaller diameter) when compared to a horizontal cross-sectional area of the column 315 as represented by the portion 305-a.

Additionally, the manufacturing process 300 may include one or more fourth operations to create the portion 305-d. The one or more fourth operations may include forming an island 330 around the column 325. In some examples, forming the island 330 around the column 325 may include forming a first material (e.g., nitride material) in the cavity 320. The manufacturing process 300 as described herein may be applied to multiple transistor structures of a memory array. For example, as shown in the top view of the portion 305-d, each of the three transistor structures (e.g., the first transistor structure, the second transistor structure, and the third transistor structure) may include an island 330 that surrounds a column 325 of its respective column 315 (or bit line contact).

Additionally, the manufacturing process 300 may include one or more fifth operations to create the portion 305-e. The one or more fifth operations may include removing at least a part of the column 325 to form a cavity in the island 330. Additionally, or alternatively, the one or more fifth operations may include forming an active area 335 in the island 330. In some examples, forming the active area may include forming a second material (e.g., polysilicon) in the cavity of the island 330. Additionally, or alternatively, the one or more fifth operations may include forming one or more layers 350 (e.g., a layer 350-a and a layer 350-b) on the layer 345. In some examples, the one or more layers 350 may include oxide material or nitride material. Additionally, the one or more fifth operations may include removing a portion of the one or more layers 350 to form a cavity in the one or more layers 350 and forming a structure 340 in the one or more layers 350 by forming a third material (e.g., a metal material) in the cavity and on the active area 335.

In some examples, the manufacturing process 300 may culminate with the creation of the portion 305-e. As shown in FIG. 3, the portion 305-e may include the column 310-a, the column 310-b, and the column 315 each of which extends through the layer 345. Further, the portion 305-e may include the active area 335 coupled with the column 315 and the structure 340. In some examples, the structure 340 may be an example of a metal contact. The structure 340 may couple directly to a respective bit line of the array or a component associated with the respective bit line (e.g., a bit line decoder, a column decoder, among other components). Further, the portion 305-e may include the island 330 that at least partially surrounds the active area 335. In some examples, the active area 335 may refer to a region in which the bit line makes electrical contact with the respective transistor structure or more specifically, the silicon region of the respective transistor structure.

In some examples, a horizonal cross-sectional area of the active area may be smaller than a cross-sectional area of at least a portion of the column 315. As a result, a horizontal distance between the active area 335 and the column 310-a or the column 310-b may be greater than a horizontal distance between the column 315 and the column 310-a or the column 310-b. Further, the portion 305-e may include the structure 340 coupled with the active area 335 and a respective bit line of the array. Further, the portion 305-e may include one or more layers 350 on the layer 345 that includes the structure 340. Using the manufacturing process 300, the active area of the bit line contact may be reduced allowing for isolation between the bit line contact and memory cell contacts of neighboring transistor structures.

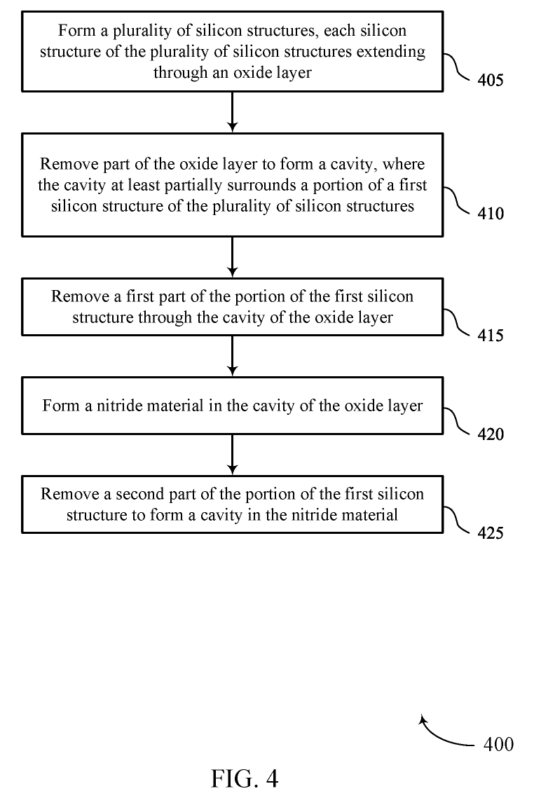

FIG. 4 shows a flowchart illustrating a method 400 that supports techniques for bit line contact active area reduction in accordance with examples as disclosed herein. The operations of method 400 may be implemented by a manufacturing system or its components as described herein. For example, the operations of method 400 may be performed by a manufacturing system as described with reference to FIGS. 1 through 3. In some examples, a manufacturing system may execute a set of instructions to control the functional elements of the device to perform the described functions. Additionally, or alternatively, the manufacturing system may perform aspects of the described functions using special-purpose hardware.

At 405, the method may include forming a plurality of silicon structures, each silicon structure of the plurality of silicon structures extending through an oxide layer. In some examples, aspects of the operations of 405 may be performed by one or more components of FIGS. 1 through 3.

At 410, the method may include removing part of the oxide layer to form a cavity, where the cavity at least partially surrounds a portion of a first silicon structure of the plurality of silicon structures. In some examples, aspects of the operations of 410 may be performed by one or more components of FIGS. 1 through 3.

At 415, the method may include removing a first part of the portion of the first silicon structure through the cavity of the oxide layer. . In some examples, aspects of the operations of 415 may be performed by one or more components of FIGS. 1 through 3.

At 420, the method may include forming a nitride material in the cavity of the oxide layer. . In some examples, aspects of the operations of 420 may be performed by one or more components of FIGS. 1 through 3.

At 425, the method may include removing a second part of the portion of the first silicon structure to form a cavity in the nitride material. In some examples, aspects of the operations of 425 may be performed by one or more components of FIGS. 1 through 3.

In some examples, an apparatus as described herein may perform a method or methods, such as the method 400. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for forming a plurality of silicon structures, each silicon structure of the plurality of silicon structures extending through an oxide layer; removing part of the oxide layer to form a cavity, where the cavity at least partially surrounds a portion of a first silicon structure of the plurality of silicon structures; removing a first part of the portion of the first silicon structure through the cavity of the oxide layer; forming a nitride material in the cavity of the oxide layer; and removing a second part of the portion of the first silicon structure to form a cavity in the nitride material.

Aspect 2: The method, apparatus, or non-transitory computer-readable medium of aspect 1, further including operations, features, circuitry, logic, means, or instructions, or any combination thereof for forming a polysilicon material in the cavity of the nitride material.

Aspect 3: The method, apparatus, or non-transitory computer-readable medium of aspect 2, further including operations, features, circuitry, logic, means, or instructions, or any combination thereof for forming a metal material on the polysilicon material.

Aspect 4: The method, apparatus, or non-transitory computer-readable medium of aspect 3, further including operations, features, circuitry, logic, means, or instructions, or any combination thereof for forming a bit line of the memory system, where the bit line is in contact with the metal material.

Aspect 5: The method, apparatus, or non-transitory computer-readable medium of any of aspects 1 through 4, further including operations, features, circuitry, logic, means, or instructions, or any combination thereof for reducing a horizontal cross sectional area of the portion of the first silicon structure based on removing the first part of the portion of the first silicon structure.

Aspect 6: The method, apparatus, or non-transitory computer-readable medium of any of aspects 1 through 5, further including operations, features, circuitry, logic, means, or instructions, or any combination thereof for forming one or more layers on the oxide layer.

Aspect 7: The method, apparatus, or non-transitory computer-readable medium of aspect 6, where the one or more layers include the nitride material or an oxide material.

Aspect 8: The method, apparatus, or non-transitory computer-readable medium of any of aspects 1 through 7, further including operations, features, circuitry, logic, means, or instructions, or any combination thereof for forming a capacitor of a memory cell of the memory system, where the capacitor is in contact with a second silicon structure of the plurality of silicon structures.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 9: A memory system, including: a plurality of silicon structures vertically extending through an oxide layer, the plurality of silicon structures including a first set of silicon structures and a second set of silicon structures, each of the first set of silicon structures coupled with a respective bit line of the memory system and each of the second set of silicon structures coupled with a respective memory component of the memory system; and a plurality of nitride structures, each nitride structure of the plurality of nitride structures at least partially surrounding a respective silicon structure of the first set of silicon structures.

Aspect 10: The memory system of aspect 9, where the oxide layer further includes: a plurality of polysilicon structures, each polysilicon structure of the plurality of

polysilicon structures coupled with a respective silicon structure of the first set of silicon structures.

Aspect 11: The memory system of aspect 10, where a horizontal cross-sectional area of a polysilicon structure of the plurality of polysilicon structures is less than a horizontal cross-sectional area of a silicon structure of the first set of silicon structures.

Aspect 12: The memory system of any of aspects 10 through 11, where a horizontal distance between a polysilicon structure of the plurality of polysilicon structures and a silicon structure of the second set of silicon structures is greater than a horizontal distance between a silicon structure of the first set of silicon structures and the silicon structure of the second set of silicon structures.

Aspect 13: The memory system of any of aspects 10 through 12, where each nitride structure of the plurality of nitride structures at least partially surrounds a respective polysilicon structure of the plurality of polysilicon structures.

Aspect 14: The memory system of any of aspects 10 through 13, further including: a plurality of metal structures, where each metal structure of the plurality of metal structures is coupled with a respective polysilicon structure of the plurality of polysilicon structures and a respective bit line of the memory system.

Aspect 15: The memory system of aspect 14, further including: one or more layers on the oxide layer, where the one or more layers include the plurality of metal structures.

Aspect 16: The memory system of aspect 15, where the one or more layers include a nitride material or an oxide material.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “layer” and “level” may refer to an organization (e.g., a stratum, a sheet) of a geometrical structure (e.g., relative to a substrate). Each layer or level may have

three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more

functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
a plurality of silicon structures vertically extending through an oxide layer, the plurality of silicon structures comprising a first set of silicon structures and a second set of silicon structures, each of the first set of silicon structures coupled with a respective bit line of the memory system and each of the second set of silicon structures coupled with a respective memory component of the memory system; and
a plurality of nitride structures, each nitride structure of the plurality of nitride structures at least partially surrounding a respective silicon structure of the first set of silicon structures.

2. The memory system of claim 1, wherein the oxide layer further comprises:
a plurality of polysilicon structures, each polysilicon structure of the plurality of polysilicon structures coupled with a respective silicon structure of the first set of silicon structures.

3. The memory system of claim 2, wherein a horizontal cross sectional area of a polysilicon structure of the plurality of polysilicon structures is less than a horizontal cross sectional area of a silicon structure of the first set of silicon structures.

4. The memory system of claim 2, wherein a horizontal distance between a polysilicon structure of the plurality of polysilicon structures and a silicon structure of the second set of silicon structures is greater than a horizontal distance between a silicon structure of the first set of silicon structures and the silicon structure of the second set of silicon structures.

5. The memory system of claim 2, wherein each nitride structure of the plurality of nitride structures at least partially surrounds a respective polysilicon structure of the plurality of polysilicon structures.

6. The memory system of claim 2, further comprising:
a plurality of metal structures, wherein each metal structure of the plurality of metal structures is coupled with a respective polysilicon structure of the plurality of polysilicon structures and a respective bit line of the memory system.

7. The memory system of claim 6, further comprising:
one or more layers on the oxide layer, wherein the one or more layers comprise the plurality of metal structures.

8. The memory system of claim 7, wherein the one or more layers comprise a nitride material or an oxide material.

9. A method for manufacturing a memory system, comprising:
forming a plurality of silicon structures, each silicon structure of the plurality of silicon structures extending through an oxide layer;
removing part of the oxide layer to form a cavity, wherein the cavity at least partially surrounds a portion of a first silicon structure of the plurality of silicon structures;
removing a first part of the portion of the first silicon structure through the cavity of the oxide layer;
forming a nitride material in the cavity of the oxide layer; and
removing a second part of the portion of the first silicon structure to form a cavity in the nitride material.

10. The method of claim 9, further comprising:
forming a polysilicon material in the cavity of the nitride material.

11. The method of claim 10, further comprising:
forming a metal material on the polysilicon material.

12. The method of claim 11, further comprising:
forming a bit line of the memory system, wherein the bit line is in contact with the metal material.

13. The method of claim 9, further comprising:
reducing a horizontal cross sectional area of the portion of the first silicon structure based on removing the first part of the portion of the first silicon structure.

14. The method of claim 9, further comprising:
forming one or more layers on the oxide layer.

15. The method of claim 14, wherein the one or more layers comprise the nitride material or an oxide material.

16. The method of claim 9, further comprising:
forming a capacitor of a memory cell of the memory system, wherein the capacitor is in contact with a second silicon structure of the plurality of silicon structures.

17. A apparatus for manufacturing a memory system, comprising:
one or more controllers configured to cause the apparatus to:
form a plurality of silicon structures, each silicon structure of the plurality of silicon structures extending through an oxide layer;
remove part of the oxide layer to form a cavity, wherein the cavity at least partially surrounds a portion of a first silicon structure of the plurality of silicon structures;
remove a first part of the portion of the first silicon structure through the cavity of the oxide layer;
form a nitride material in the cavity of the oxide layer; and
remove a second part of the portion of the first silicon structure to form a cavity in the nitride material.

18. The apparatus of claim 17, wherein the one or more controllers are further configured to cause the apparatus to:
form a polysilicon material in the cavity of the nitride material.

19. The apparatus of claim 17, wherein the one or more controllers are further configured to cause the memory system to:
reduce a horizontal cross sectional area of the portion of the first silicon structure based on removing the first part of the portion of the first silicon structure.

20. The apparatus of claim 17, wherein the one or more controllers are further configured to cause the apparatus to:
form one or more layers on the oxide layer.
